(19) United States
(12) Patent Application Publication
(10) Pub. No.: US 2025/0293033 A1
(43) Pub. Date: Sep. 18, 2025

(54) BONDED WAFER PROCESSING METHOD

(71) Applicant: DISCO CORORATION, Tokyo (JP)

(72) Inventor: Atsushi KOMATSU, Tokyo (JP)

(21) Appl. No.: 19/062,230

(22) Filed: Feb. 25, 2025

(30) Foreign Application Priority Data
Mar. 13, 2024 (JP) 2024-038573

(51) Int. Cl. H01L 21/304; H01L 21/66

(52) U.S. Cl. CPC H01L 21/304; H01L 22/12

(57) ABSTRACT

A processing method for a bonded wafer includes forming, in an outer peripheral portion of a first wafer, a first step portion having a depth that does not reach a second wafer and by which the first wafer remains, and removing the outer peripheral portion of the first wafer by rotating the holding table about a rotational shaft in a state in which a lower end of a second cutting blade is positioned to a position where a joining layer is present, in which, in the removing the outer peripheral portion of the first wafer, the second cutting blade and the holding table are rotated such that the direction of the velocity vector of the lower end of the second cutting blade becomes opposite the direction of the velocity vector of the bonded at a position corresponding to the lower end of the second cutting blade.

### BACKGROUND OF THE INVENTION

### Field of the Invention

The present invention relates to a processing method for a bonded wafer in which a first wafer and a second wafer are bonded with a joining layer sandwiched therebetween.

### Description of the Related Art

In recent years, bonded wafers are increasingly handled as workpieces to be processed. Bonded wafers are obtained by a first wafer and a second wafer being joined in such a manner as to be superimposed one on the other via a joining layer, the first wafer and the second wafer each having a chamfered portion (also called a bevel portion) on an outer peripheral portion of both sides. Removing the chamfered portion on both sides of the first wafer over the entire circumferential direction by applying edge trimming to the outer peripheral portion of the first wafer with use of a cutting blade before the first wafer of the bonded wafer is thinned by grinding is known (see, for example, Japanese Patent Laid-open No. 2017-92413).

When edge trimming is to be applied to the outer peripheral portion of the first wafer, if the outer peripheral portion of the first wafer is cut with a lower end of the cutting blade positioned to a height corresponding to a boundary between the first wafer and the joining layer for the purpose of cutting only the first wafer and not the second wafer by the cutting blade, a region that is part of an annular region to which edge trimming has been applied in the first wafer and that is in contact with the joining layer is not completely cut and removed and partially remains in some cases.

Further, when a void due to a joining failure has occurred between the remaining region in the first wafer and the joining layer, defects occur in the bonded wafer at the time of applying heat treatment to the bonded wafer obtained after edge trimming in the subsequent steps. Hence, in the annular region to which edge trimming has been applied, it is desirable that the first wafer be completely cut and removed.

As such, for the purpose of eliminating the remaining region of the first wafer in the annular region to which edge trimming has been applied in the first wafer, one possible method is to cut a region that is part of the outer peripheral portion of the second wafer and that is in the vicinity of the joining layer, in addition to the first wafer and the joining layer, by lowering the lower end of the cutting blade to a position of the second wafer.

However, when the outer peripheral portion of the second wafer is exposed by such cutting being performed, the exposed outer peripheral portion of the second wafer would also be etched in the subsequent etching step (specifically, the etching step performed for eliminating cutting damages caused to the ground surface of the first wafer at the time of grinding processing of the first wafer).

In a case where devices are formed on one surface that is positioned near the joining layer in the second wafer, if the outer peripheral portion of the second wafer is etched, such defects that devices located in the vicinity of the outer peripheral portion on one surface of the second wafer are broken occur. Hence, in edge trimming, it is preferable that the second wafer not be cut and the joining layer be left over the entire outer peripheral portion on one surface of the second wafer such that the outer peripheral portion on one surface of the second wafer is not exposed.

Yet, in edge trimming, due to the nature of cutting processing using a cutting blade, a certain degree of variation occurs in the cutting depth in the circumferential direction of the bonded wafer. Hence, there exist such circumstances that processing control of completely removing the first wafer but leaving the joining layer such that the outer peripheral portion of the second wafer is not exposed over the entire outer peripheral portion of the bonded wafer is not easy.

### SUMMARY OF THE INVENTION

The present invention has been made in view of the abovementioned problem, and has, as an object thereof, completely removing the first wafer but leaving the joining layer such that the outer peripheral portion of the second wafer is not exposed over the entire outer peripheral portion of the bonded wafer when edge trimming is applied to the first wafer of the bonded wafer.

In accordance with an aspect of the present invention, there is provided a bonded wafer processing method for a bonded wafer in which a first wafer and a second wafer are bonded with a joining layer sandwiched therebetween. The method includes holding, on a holding table rotatable about a predetermined rotational shaft, the bonded wafer such that the first wafer is exposed, after the holding the bonded wafer, forming, in an outer peripheral portion of the first wafer, a first step portion having a depth that does not reach the second wafer and by which the first wafer remains, by rotating the holding table about the rotational shaft in a state in which a first cutting blade mounted to a distal end portion of a first spindle is caused to cut into the outer peripheral portion of the first wafer while being rotated about the first spindle, and after the forming the first step portion, removing the outer peripheral portion of the first wafer by rotating the holding table about the rotational shaft in a state in which a second cutting blade mounted to a distal end portion of a second spindle is rotated about the second spindle while a lower end of the second cutting blade is positioned to a position that is closer to the second wafer than to a bottom surface of the first step portion in a thickness direction of the bonded wafer and at which the joining layer is present. In the removing the outer peripheral portion of the first wafer, the second cutting blade and the holding table are rotated such that a direction of a velocity vector of the lower end of the second cutting blade becomes opposite a direction of a velocity vector of the bonded wafer at a position corresponding to the lower end.

Preferably, the bonded wafer processing method further includes, after the forming the first step portion but before the removing the outer peripheral portion of the bonded wafer, measuring a remaining thickness of the first wafer that remains between the bottom surface of the first step portion and the second wafer, and in the removing the outer peripheral portion of the first wafer, a position of the lower end of the second cutting blade is set according to the remaining thickness.

Moreover, preferably, in the measuring the remaining thickness of the first wafer, the remaining thickness of the first step portion is measured with use of a non-contact thickness gage that is capable of measuring a thickness without coming into contact with the bonded wafer.

In the bonded wafer processing method according to one aspect of the present invention, after the first step portion having a depth that does not reach the second wafer and by which the joining layer remains is formed, the second cutting blade and the holding table are rotated (that is, what is generally called up-cutting is performed) such that the direction of the velocity vector of the lower end of the second cutting blade becomes opposite the direction of the velocity vector of the bonded wafer at a position corresponding to the lower end of the second cutting blade, and the joining layer at the position closer to the second wafer than to the bottom surface of the first step portion is cut.

In up-cutting, the cutting blade is less likely to bite into the cutting target, compared to down-cutting. Hence, cutting load on the cutting blade, i.e., cutting resistance, is high in up-cutting, and the cutting blade is more likely to shift away from the joining layer (for example, upward). Moreover, the joining layer typically being formed of a material causing higher load on the cutting blade than those of the first wafer and the second wafer is also a factor for the cutting blade to be more likely to shift away from the joining layer.

Hence, cutting the bonded wafer by up-cutting in a state in which the lower end of the second cutting blade is positioned to a position that is closer to the second wafer than to the bottom surface of the first step portion and at which the joining layer is present can completely remove the first wafer without completely removing the joining layer (that is, while leaving the joining layer) over the entire circumferential direction of the bonded wafer, owing to the high cutting load on the second cutting blade at the joining layer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a flowchart illustrating a processing method for a bonded wafer;

FIG. 2 is a side elevational view, partly in cross section, illustrating a holding step;

FIG. 3A is a plan view illustrating a first cutting step;

FIG. 3B is a side elevational view, partly in cross section, illustrating the first cutting step;

FIG. 4 is a cross sectional view of an outer peripheral portion of the bonded wafer in which a first step portion is illustrated in an enlarged form;

FIG. 5A is a plan view illustrating a remaining thickness measuring step;

FIG. 5B is a side elevational view, partly in cross section, illustrating the remaining thickness measuring step;

FIG. 6A is a plan view illustrating a second cutting step;

FIG. 6B is a side elevational view, partly in cross section, illustrating the second cutting step;

FIG. 7 is an enlarged cross sectional view illustrating the second cutting step;

FIG. 8 is a cross sectional view of the outer peripheral portion of the bonded wafer in which a second step portion is illustrated in an enlarged form;

FIG. 9A is a schematic view illustrating a first comparative example in which the second cutting step is performed by down-cutting;

FIG. 9B is a schematic view illustrating a second comparative example in which the second cutting step is performed by down-cutting;

FIG. 10 is a schematic view illustrating the manner of performing the second cutting step by up-cutting; and

FIG. 11 is a view indicating a result of experiment of confirming the difference between down-cutting and up-cutting.

### DETAILED DESCRIPTION OF THE PREFERRED EMBODIMENT

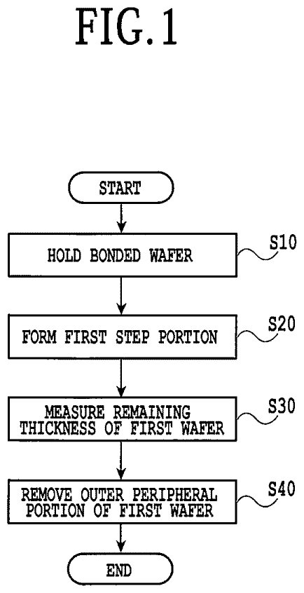

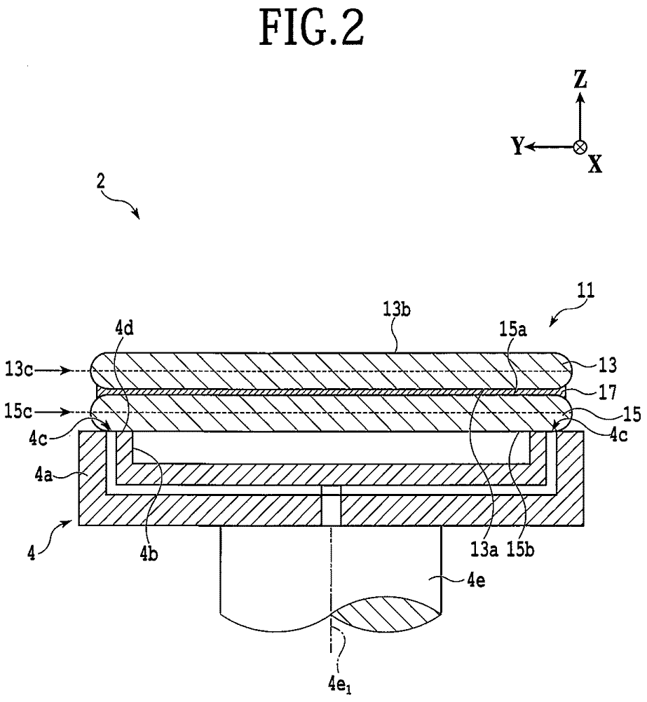

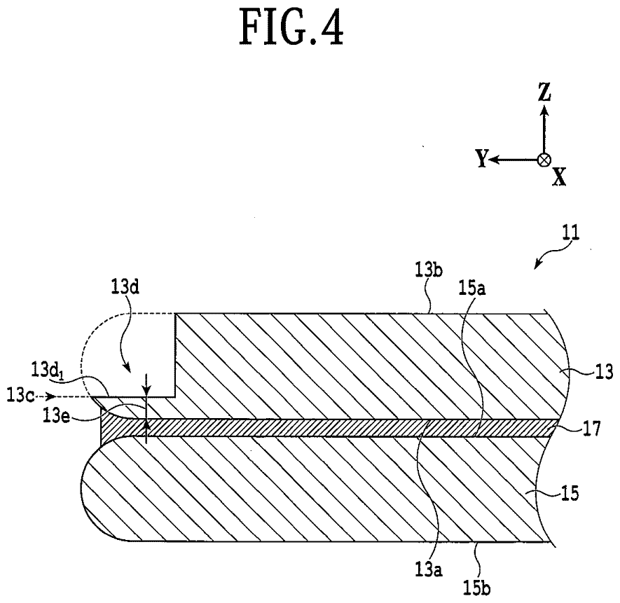

With reference to the attached drawings, an embodiment according to an aspect of the present invention is described. FIG. 1 is a flowchart illustrating a processing method for a bonded wafer 11 (see FIG. 2). According to the present embodiment, steps are carried out in the order of holding the bonded wafer 11 including a first wafer 13 and a second wafer 15 (holding step S10), forming a first step portion 13d (see FIG. 4) in the first wafer 13 (first cutting step S20), measuring a remaining thickness 13e (see FIG. 4) of the first wafer 13 (remaining thickness measuring step S30), and removing an outer peripheral portion of the first wafer 13 (second cutting step S40). First, the bonded wafer 11 that is to be processed by the processing method is described.

The bonded wafer 11 includes the first wafer 13 and the second wafer 15 each having a disk shape. Each of the first wafer 13 and the second wafer 15 includes a silicon single crystalline substrate having the same diameter (for example, 300±0.2 mm) defined by a predetermined standard such as Semiconductor Equipment and Materials International (SEMI) standards.

The first wafer 13 includes a face side 13a and a reverse side 13b each having a circular shape and each being positioned on a side opposite from each other in a thickness direction. Similarly, the second wafer 15 includes a face side 15a and a reverse side 15b each having a circular shape and each being positioned on a side opposite from each other in the thickness direction.

A chamfered portion is formed in an outer peripheral portion of each of the face side 13a and the reverse side 13b of the first wafer 13. The chamfered portion is illustrated in an exaggerated manner in FIG. 2. Note that, after the second cutting step S40, grinding processing is slated to be applied to the reverse side 13b of the first wafer 13.

In the present embodiment, a chamfered portion is similarly formed in an outer peripheral portion of each of the face side 15a and the reverse side 15b of the second wafer 15. Yet, the chamfered portion may not be provided in the outer peripheral portion of each of the face side 15a and the reverse side 15b of the second wafer 15.

The ratio of the diameter to the thickness is sufficiently large in each of the first wafer 13 and the second wafer 15, and the region in which the chamfered portion is formed is an extremely narrow region in the outer peripheral portion. For example, the chamfered portion is formed in a range with a width of less than 1.0 mm from outer peripheral edges 13c and 15c in a radial direction, in the first wafer 13 and the second wafer 15 each having a diameter of 300 mm.

On a central side of the face side 13a of the first wafer 13 with respect to the chamfered portion in the radial direction of the first wafer 13, a plurality of devices (not illustrated) exemplified by integrated circuits (ICs) are formed. Similarly, on a central side of the face side 15a of the second wafer 15 with respect to the chamfered portion in the radial direction of the second wafer 15, a plurality of devices (not illustrated) exemplified by ICs are formed.

Yet, the devices may not be formed in the second wafer 15. In this case, the second wafer 15 functions as a support substrate that supports the first wafer 13 in a thinning step of the first wafer 13. The support substrate is only required to be a substrate having substantially the same diameter as the first wafer 13, and may be formed of a semiconductor, resin, metal, ceramics, or glass, for example.

When no devices are formed in the second wafer 15, there occur no such defects that the devices located in the vicinity of the outer peripheral portion of the face side 15a of the second wafer 15 are broken in an etching step that is to be performed after edge trimming. Hence, removing the first wafer 13 and the outer peripheral portion of the joining layer 17 such that the second wafer 15 is exposed may seem to pose no problem.

However, when edge trimming is applied to the bonded wafer 11 such that the second wafer 15 is exposed, the face side 15a of the second wafer 15 is almost inevitably cut. This makes it difficult to reuse the second wafer 15 after peeling off the first wafer 13 from the second wafer 15, leaving no choice but to discard the second wafer 15.

Hence, even when no devices are formed in the second wafer 15, completely removing the first wafer 13 but leaving the joining layer 17 such that the outer peripheral portion of the second wafer 15 is not exposed over the entire outer peripheral portion of the bonded wafer 11 has such an advantage that the support substrate, i.e., the second wafer 15, can be reused.

The face side 13a of the first wafer 13 and the face side 15a of the second wafer 15 are aligned in such a manner that centers of the face side 13a and the face side 15a substantially coincide. Moreover, the face side 13a and the face side 15a are joined via the joining layer 17. That is, in the bonded wafer 11, the first wafer 13 and the second wafer 15 are bonded with the joining layer 17 sandwiched therebetween.

The joining layer 17 is, for example, an oxide film configured by silicon oxide or the like, a nitride film configured by silicon nitride or the like, an oxynitride film configured by silicon oxynitride or the like, or a resin film configured by an adhesive agent such as epoxy resin. The joining layer 17 according to the present embodiment is an oxide film that is provided on the face side 13a of the first wafer 13 and that functions as a passivation film, for example.

Yet, the joining layer 17 may be provided on the face side 15a of the second wafer 15 or provided on each of the face side 13a and the face side 15a. Moreover, the joining layer 17 may be a film provided separately from the first wafer 13 and the second wafer 15 in order to join the first wafer 13 and the second wafer 15.

For example, the joining layer 17 is a film provided separately from the first wafer 13 and the second wafer 15 by plasma chemical vapor deposition (CVD), for example. The separately provided joining layer 17 is, for example, an oxide film, a nitride film, or an oxynitride film, and is formed on the face side 13a of the first wafer 13 and/or the face side 15a of the second wafer 15.

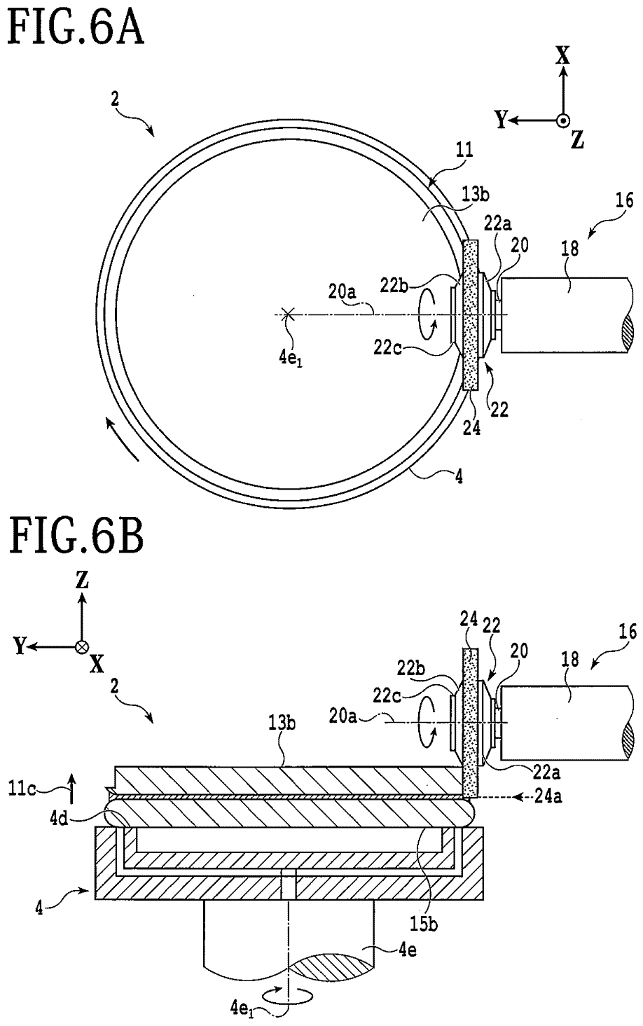

If the joining layer 17 is an inorganic film such as an oxide film, the inorganic film is hard compared to a silicon single crystalline substrate. Hence, at the time of cutting, due to the high cutting load on the cutting blade, the cutting blade (for example, a second cutting blade 24 illustrated in FIGS. 6A and 6B) is more likely to shift away from the joining layer 17 (for example, upward).

Further, if the joining layer 17 is a resin film such as epoxy resin, the joining layer 17 is not hard compared to an inorganic film, but the second cutting blade 24 is more likely to suffer clogging, i.e., loading, at the time of cutting the joining layer 17, so that the cutting load on the cutting blade becomes high. Due to this high cutting load, as in the case of the inorganic film, the second cutting blade 24 is more likely to shift away from the joining layer 17.

Note that the joining layer 17 according to the present embodiment is provided in a region having a circle shape with a radius from the center of the face side 13a to a predetermined position in the chamfered portion in the radial direction of the face side 13a; the joining layer 17 does not reach the outer peripheral edge 13c of the first wafer 13. Hence, the joining layer 17 is in contact with the second wafer 15 in a circular region that does not reach the outer peripheral edge 15c in the radial direction of the second wafer 15.

Next, a cutting apparatus 2 used in the processing method for the bonded wafer 11 is explained. As illustrated in FIG. 2, the cutting apparatus 2 includes a disk-shaped chuck table (holding table) 4. The chuck table 4 has a disk-shaped frame body 4a. In the central portion of an upper surface of the frame body 4a, a disk-shaped recessed portion 4b is provided. On an upper surface of an annular protruding portion located on the outer side of the recessed portion 4b, an annular suction groove 4c is provided.

To the suction groove 4c, negative pressure from a vacuum generation apparatus (not illustrated) such as a vacuum pump and an ejector is transmitted. The upper surface of the annular protruding portion functions as a holding surface 4d for holding under suction the bonded wafer 11. The annular holding surface 4d is disposed substantially parallel to an XY plane configured by an X-axis direction and a Y-axis direction of the cutting apparatus 2.

A rotational shaft 4e is coupled to a bottom portion of the chuck table 4. The rotational shaft 4e can rotate by an unillustrated motor. The rotational shaft 4e is disposed along a Z-axis direction perpendicular to the X-axis direction and the Y-axis direction in the cutting apparatus 2. By the rotational shaft 4e being rotated, the chuck table 4 can rotate about the rotational shaft 4e (that is, a rotation center 4e₁).

A rotation direction of the rotational shaft 4e may either be clockwise or counterclockwise in plan view. Moreover, the rotational speed (that is, a rotational angle per unit time) of the rotational shaft 4e may be set to a desired value.

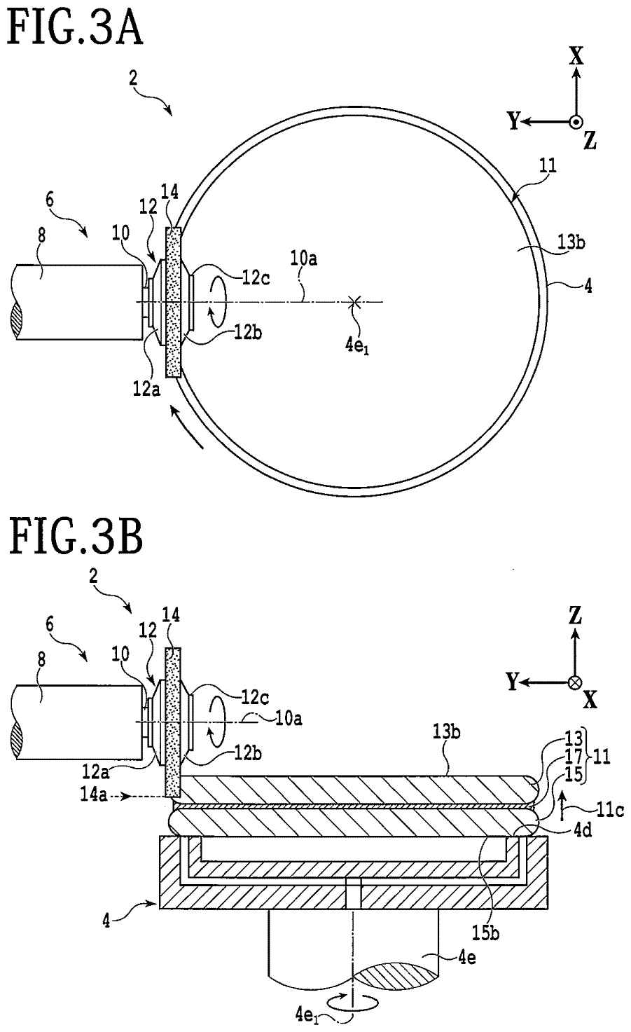

As illustrated in FIGS. 3A and 3B, a first cutting unit 6 is provided above the chuck table 4. The first cutting unit 6 according to the present embodiment applies what is generally called down-cutting to the bonded wafer 11 in cooperation with the chuck table 4.

The first cutting unit 6 includes a spindle housing 8 a longitudinal portion of which is disposed long the Y-axis direction. In the spindle housing 8, part of a cylindrical first spindle 10 is housed in a rotatable manner by an air bearing (that is, a static pressure pneumatic bearing). A distal end portion of the first spindle 10 projects outward from the spindle housing 8.

In the vicinity of a proximal end portion of the first spindle 10, a motor (not illustrated) is provided. In FIG. 3B, the first spindle 10 is illustrated as rotating counterclockwise when the first spindle 10 is viewed over the chuck table 4 in the Y-axis direction, but the first spindle 10 may alternatively rotate clockwise.

A longitudinal direction of the first spindle 10 is disposed substantially parallel to the Y-axis direction. To the distal end portion of the first spindle 10, a first cutting blade 14 having a circular ring-shaped cutting edge is mounted with use of a blade mounting mechanism 12.

The blade mounting mechanism 12 has a disk-shaped receiving flange portion 12a. The central portion of the receiving flange portion 12a in the radial direction is fixed to the distal end portion of the first spindle 10 by an unillustrated bolt, etc. The receiving flange portion 12a has a cylindrical boss portion (not illustrated) at the central portion in the radial direction.

This boss portion is inserted into a circular opening of the first cutting blade 14. The first cutting blade 14 according to the present embodiment is what is generally called a hubless-type (that is, a washer-type) cutting blade, and is configured by only a cutting edge including abrasive grains, a bonding material, and the like.

Since the first cutting blade 14 is used for what is generally called coarse grinding, the average grain diameter of the abrasive grains thereof is relatively large. For example, the abrasive grains of the first cutting blade 14 each have a predetermined grain size of #240 or more but less than #1500 (for example, #400). Typically, the smaller the numerical value indicating the grain size, the larger the average grain diameter of the abrasive grains.

In the present embodiment, the grain size is indicated based on JIS R 6001-2:2017 (Bonded abrasives-Determination and designation of grain size distribution-Part 2 Microgrits) included in Japanese Industrial Standards (JIS). The grain size is, for example, specified with use of a sedimentation tube test method, an electric resistance test, and the like. Note that the grain size may be indicated based on or according to the indication normally used in the business field of manufacturing and selling grindstones.

The boss portion of the receiving flange portion 12a is inserted into a circular opening of a circular ring-shaped pressing flange portion 12b in such a manner as to sandwich the first cutting blade 14 by the receiving flange portion 12a and the pressing flange portion 12b. On the distal end portion of the boss portion, a male screw is formed.

To the male screw of the boss portion, a female screw of a circular ring-shaped pressing flange 12c in which the female screw is formed in a circular ring-shaped inner peripheral surface is fastened. In this manner, the first cutting blade 14 is fixed to the first spindle 10 in a state of being sandwiched by the receiving flange portion 12a and the pressing flange portion 12b.

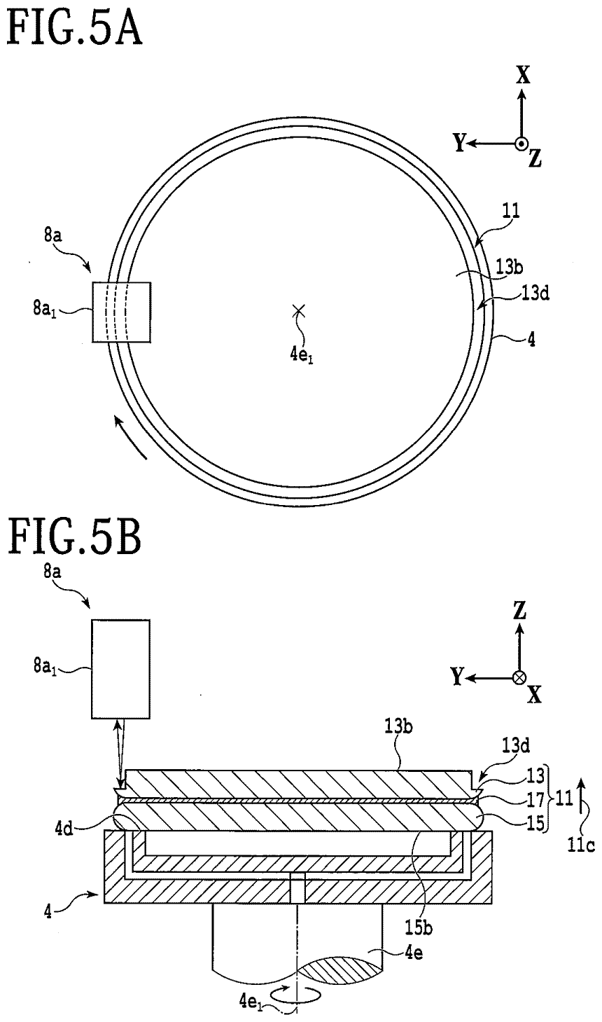

A non-contact thickness gage 8a is provided in the cutting apparatus 2 (see FIGS. 5A and 5B). The non-contact thickness gage 8a is, for example, a spectroscopic thickness gage that uses interference of light in a wideband wavelength, a thickness gage that uses infrared rays, or a thickness gage that uses ultrasonic waves. The non-contact thickness gage 8a is capable of measuring the thickness of a thin film without coming into contact with the bonded wafer 11.

For example, if the non-contact thickness gage 8a is a spectroscopic thickness gage, the non-contact thickness gage 8a includes a super luminescent diode (SLD) light source (not illustrated), a sensor head 8a₁, a spectroscope (not illustrated), a waveform analyzing section (not illustrated) that is implemented by a processor executing a program, and the like. The sensor head 8a1 is fixed to a lateral side of the spindle housing 8.

The cutting apparatus 2 is a dicing saw of a parallel dual structure in which two spindles are disposed in parallel with each other. As illustrated in FIGS. 6A and 6B, a second cutting unit 16 is disposed above the chuck table 4. The second cutting unit 16 includes a spindle housing 18 a longitudinal portion of which is disposed along the Y-axis direction.

Inside the spindle housing 18, part of a cylindrical second spindle 20 is housed in a rotatable manner by an air bearing. A longitudinal direction of the second spindle 20 is disposed substantially parallel with the Y-axis direction. In the vicinity of a proximal end portion of the second spindle 20, a motor (not illustrated) is provided.

In FIG. 6A, the second spindle 20 is illustrated as rotating clockwise when the second spindle 20 is viewed over the chuck table 4 in the Y-axis direction, but the second spindle 20 can also rotate counterclockwise.

A distal end portion of the second spindle 20 projects outward from the spindle housing 18. To the distal end portion of the second spindle 20, a second cutting blade 24 having a circular ring-shaped cutting edge is mounted with use of a blade mounting mechanism 22.

Similarly to the blade mounting mechanism 12, the blade mounting mechanism 22 includes a receiving flange portion 22a, a pressing flange portion 22b, and a pressing nut 22c each having a disk shape. The second cutting blade 24 according to the present embodiment is also a hubless-type cutting blade.

Since the second cutting blade 24 is used for what is generally called finish grinding, the average grain diameter of the abrasive grains thereof is relatively small. For example, the abrasive grains of the second cutting blade 24 each have a predetermined grain size of equal to or more than #1500 but equal to or less than #3000 (for example, #1500).

Fastening the pressing nut 22c to the distal end portion of the boss portion after the second cutting blade 24 is inserted into the boss portion of the receiving flange portion 22a and further the boss portion is inserted into the circular opening of the pressing flange portion 22b fixes the second cutting blade 24 to the second spindle 20 in a state of being sandwiched by the receiving flange portion 22a and the pressing flange portion 22b.

Next, with reference to FIGS. 2 through 8, the processing method for the bonded wafer 11 is described. FIG. 2 is a side elevational view, partly in cross section, illustrating the holding step S10. In the holding step S10, first, the bonded wafer 11 is placed on the chuck table 4 such that the reverse side 13b of the first wafer 13 is exposed upward. At this time, the center of the bonded wafer 11 in the radial direction and the rotation center 4e₁ are caused to substantially match.

Next, negative pressure is caused to act on the suction groove 4c. As a result, the bonded wafer 11 is held under suction on the holding surface 4d. After the holding step S10, in the first cutting step S20, the first cutting blade 14 cuts the outer peripheral portion of the first wafer 13 to form the first step portion 13d (see FIG. 4) not reaching the joining layer 17.

FIG. 3A is a plan view illustrating the first cutting step S20, while FIG. 3B is a side elevational view, partly in cross section, illustrating the first cutting step S20. In FIGS. 3A and 3B, an extension of the rotation center 10a of the first spindle 10 is indicated by a dash-dotted line. Further, in FIG. 3A, a rotation center 4e₁ of the rotational shaft 4e is indicated by a cross sign, and in FIG. 3B, the rotation center 4e₁ is indicated by a dash-dotted line.

In the first cutting step S20, the first step portion 13d is formed in the outer peripheral portion of the first wafer 13 by the chuck table 4 being rotated about the rotational shaft 4e in a state in which the first cutting blade 14 is caused to cut into the outer peripheral portion of the first wafer 13 while being rotated about the first spindle 10.

Specifically, first, the chuck table 4 is caused to make translational motion in the X-axis direction while a lower end 14a of the first cutting blade 14 rotating at high speed (for example, 30000 rpm) is positioned on an upper side by a predetermined distance (for example, 10 μm) from the face side 13a of the first wafer 13, so that the first cutting blade 14 is caused to cut into the outer peripheral portion of the first wafer 13 (that is, caused to perform slide-in cutting).

After the chuck table 4 has been moved along the X-axis direction to a position where the extension of the rotation center 10a of the first spindle 10 intersects the rotation center 4e₁ of the rotational shaft 4e (see FIG. 3A), the chuck table 4 starts rotating. The rotational angle of the rotational shaft 4e per unit time is, for example, 5°/s.

Rotating the chuck table 4 at least once cuts the outer peripheral portion of the first wafer 13 over the entire circumferential direction of the first wafer 13 and removes equal to or more than 50% but equal to or less than 99% of the thickness of the first wafer 13 in the outer peripheral portion of the first wafer 13. In this manner, the annular first step portion 13d is formed.

In the first cutting step S20, rotation directions of the first cutting blade 14 and the chuck table 4 are adjusted such that the rotation direction of the first cutting blade 14 (that is, a rotation direction of the first spindle 10) leads to down-cutting being performed for the bonded wafer 11.

In order to cut the bonded wafer 11 with down-cutting, the first cutting blade 14 and the chuck table 4 are rotated such that the direction of the velocity vector of the lower end 14a of the first cutting blade 14 becomes the same as the direction of the velocity vector of the bonded wafer 11 at the position corresponding to the lower end 14a in the XY plane.

At this time, the first cutting blade 14 rotates toward the lower end 14a of the first cutting blade 14 from the reverse side 13b of the first wafer 13 that is in contact with the first cutting blade 14, while the outer peripheral portion of the bonded wafer 11 rotates in such a manner as to approach the first cutting blade 14.

In the present embodiment, the first cutting blade 14 is rotated counterclockwise when the first cutting blade 14 is viewed over the chuck table 4 in the Y-axis direction, and the chuck table 4 is rotated clockwise in plan view.

Adopting down-cutting in the first cutting step S20 can prevent chipping in the reverse side 13b or peeling off of films provided in the reverse side 13b and also adjust, with high accuracy, the depth of the first step portion 13d that has actually been formed to the set depth of the first step portion 13d, comparing to adopting up-cutting.

Yet, down-cutting is not essential in the first cutting step S20. In the first cutting step S20, while down-cutting has much more advantages than up-cutting, up-cutting may still be adopted. Note that, when up-cutting is to be carried out in the first cutting step S20, up-cutting can be realized by reversing the rotation direction of the first cutting blade 14 or reversing a rotation direction of the chuck table 4 in FIGS. 3A and 3B.

FIG. 4 is a cross sectional view of the outer peripheral portion of the bonded wafer 11 in which the first step portion 13d is illustrated in an enlarged form. Note that forming the first step portion 13d allows the outer peripheral edge 13c to move to a position close to the second wafer 15 compared to that in a state in which the first step portion 13d is yet to be formed.

As illustrated in FIG. 4, when viewed with the reverse side 13b as the starting point, the first step portion 13d has a depth that does not reach the second wafer 15 and by which the first wafer 13 remains. The remaining thickness 13e of the first wafer 13 remaining below the first step portion 13d is, for example, approximately 10 μm.

In the first cutting step S20, forming the first step portion 13d by the first cutting blade 14 that has abrasive grains of a relatively large grain diameter can shorten the working time and reduce the wear of the cutting blade compared to the case in which the first step portion 13d is formed by the second cutting blade 24 that has abrasive grains of a relatively small grain diameter.

After the first cutting step S20 but before the second cutting step S40, the remaining thickness 13e of the first wafer 13 that remains between a bottom surface 13d1 of the first step portion 13d and the second wafer 15 is measured by the non-contact thickness gage 8a (remaining thickness measuring step S30).

FIG. 5A is a plan view illustrating the remaining thickness measuring step S30, while FIG. 5B is a side elevational view, partly in cross section, illustrating the remaining thickness measuring step S30. In the remaining thickness measuring step S30, first, the position of the first cutting unit 6 in the Y-axis direction and the position of the chuck table 4 in the X-axis direction are adjusted, so that the sensor head 8a1 of the non-contact thickness gage 8a is disposed right above the first step portion 13d. Along with this, the position of the first cutting unit 6 in the Z-axis direction is adjusted, to adjust the position of the sensor head 8a1 in the Z-axis direction.

Next, while light, ultrasonic waves, and the like are applied from the sensor head 8a1, the chuck table 4 is rotated at a predetermined rotational angle per unit time. In reference to the data obtained via the sensor head 8a1, the non-contact thickness gage 8a measures the remaining thickness 13e of the first wafer 13 that remains below the first step portion 13d. After the remaining thickness measuring step S30, the second cutting step S40 is performed.

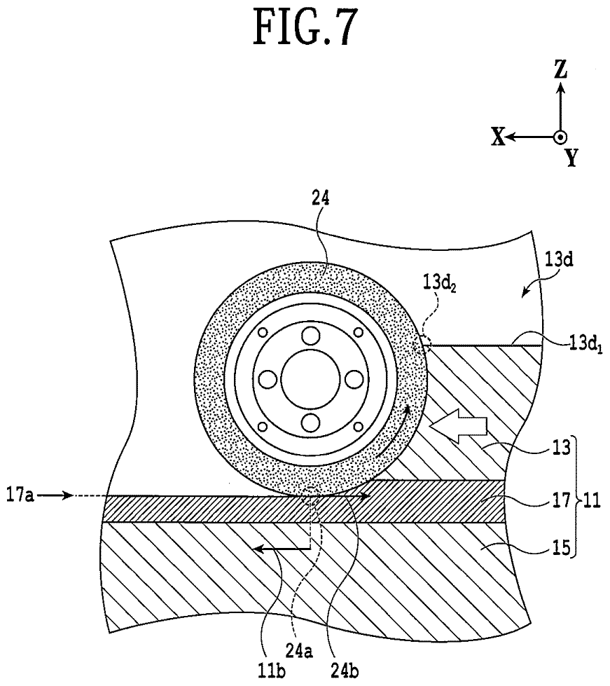

FIG. 6A is a plan view illustrating the second cutting step S40, while FIG. 6B is a side elevational view, partly in cross section, illustrating the second cutting step S40. FIG. 7 is an enlarged cross sectional view illustrating the second cutting step S40.

In the second cutting step S40, first, the second cutting blade 24 is rotated about the second spindle 20, and a lower end 24a of the second cutting blade 24 is positioned to a predetermined position 17a (see FIG. 7) that is closer to the second wafer 15 than to the bottom surface 13d1 of the first step portion 13d in the thickness direction 11c of the bonded wafer 11 and at which the joining layer 17 is present.

In the second cutting step S40, with the bottom surface 13d1 of the first step portion 13d being used as a reference, the extent to which the lower end 24a of the second cutting blade 24 is to be disposed further lower from the bottom surface 13d1 is set. Specifically, setting the position of the lower end 24a of the second cutting blade 24 based on the remaining thickness 13e obtained in the remaining thickness measuring step S30 makes it possible to set the position of the lower end 24a to the predetermined position 17a with high accuracy.

In the second cutting step S40, in particular, the second cutting blade 24 and the chuck table 4 are rotated (see FIG. 7) such that a direction 24b of the velocity vector of the second cutting blade 24 at the lower end 24a of the second cutting blade 24 becomes opposite a direction 11b of the velocity vector of the bonded wafer 11 at the position corresponding to the lower end 24a in the XY plane. Note that, in FIG. 7, an open arrow indicates a rotation direction in the outer peripheral portion of the bonded wafer 11.

In the second cutting step S40, the second cutting blade 24 rotates toward a contact point 13d2 of the bottom surface 13d1 of the first step portion 13d that comes into contact with the second cutting blade 24 from the lower end 24a of the second cutting blade 24 (that is, performs up-cutting), and the outer peripheral portion of the bonded wafer 11 rotates in such a manner as to approach the second cutting blade 24.

The rotational speed of the second cutting blade is, for example, 30000 rpm. Next, in a state in which the lower end 24a of the second cutting blade 24 rotating at high speed is positioned to the predetermined position 17a, the chuck table 4 is caused to make translational motion along the X-axis direction to a position where the extension of the rotation center 20a intersects the rotation center 4e₁ (that is, slide-in cutting is performed) (see FIG. 6A).

Subsequently, the chuck table 4 is rotated about the rotational shaft 4e at 5°/s, for example, and the outer peripheral portion of the first wafer 13 is removed. Rotating the chuck table 4 at least once cuts the outer peripheral portion of the first wafer 13 over the entire circumferential direction of the first wafer 13.

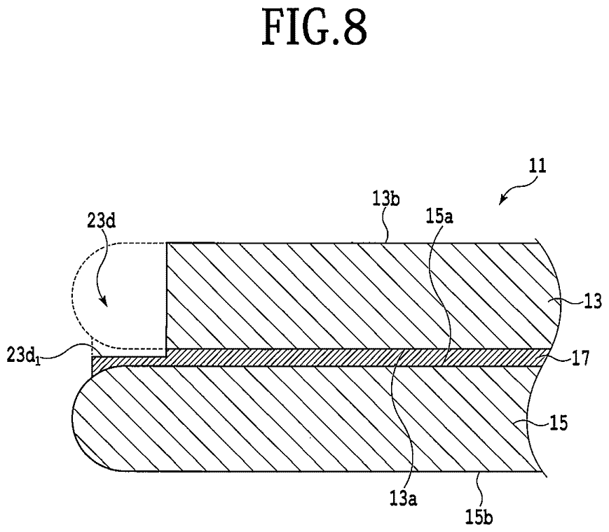

In this manner, a second step portion 23d is formed (see FIG. 8). In the second step portion 23d, the first wafer 13 directly below the first step portion 13d is removed, but the joining layer 17 in the vicinity of the face side 13a of the first wafer 13 is not completely removed over the circumferential direction. That is, in the second step portion 23d, the joining layer 17 remains over the circumferential direction of the bonded wafer 11.

FIG. 8 is a cross sectional view of the outer peripheral portion of the bonded wafer 11 in which the second step portion 23d formed in the second cutting step S40 is illustrated in an enlarged form. As illustrated in FIG. 8, at a bottom surface 23d1 of the second step portion 23d, the joining layer 17 is not completely removed in the thickness direction 11c, and remains over the entire circumferential direction of the bonded wafer 11.

In the up-cutting adopted in the second cutting step S40, compared to down-cutting, the second cutting blade 24 is less likely to bite into the cutting target, and hence, the cutting load on the cutting blade becomes great, and the second cutting blade 24 is more likely to shift away from the joining layer 17 (for example, upward).

Further, the material used as the joining layer 17 also typically causes high cutting load compared to those of the first wafer 13 and the second wafer 15; this is also another factor for the second cutting blade 24 to be more likely to shift away from the joining layer 17.

Hence, in the second cutting step S40, if the bonded wafer 11 is cut by up-cutting in a state in which the lower end 24a of the second cutting blade 24 is positioned to the predetermined position 17a that is closer to the second wafer 15 than to the bottom surface 13d1 of the first step portion 13d and at which the joining layer 17 is present, the first wafer 13 can completely be removed without the joining layer 17 completely being removed over the entire circumferential direction of the bonded wafer 11 (that is, with the joining layer 17 being left) owing to the high cutting load on the second cutting blade at the joining layer 17.

In this manner, according to the present embodiment, actively utilizing the difficulty in cutting the joining layer 17 in up-cutting makes it possible to leave the joining layer 17 but completely remove the first wafer 13 over the entire circumferential direction of the bonded wafer 11.

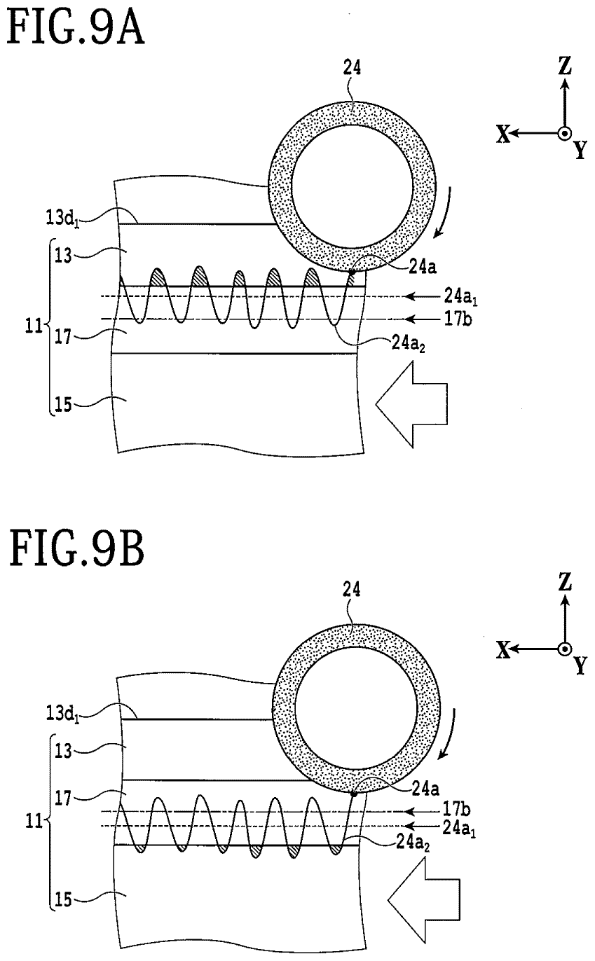

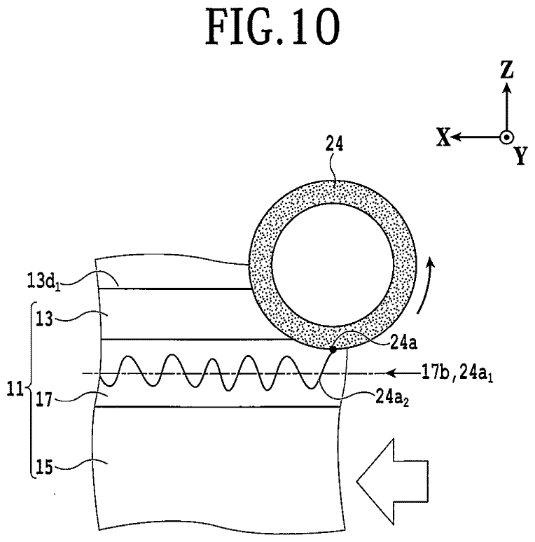

Next, with reference to FIGS. 9A, 9B, and 10, description will be made with a comparison being made between a case of performing down-cutting in the second cutting step S40 (comparative example) and a case of performing up-cutting in the second cutting step S40 (the embodiment described above). Note that, in FIGS. 9A, 9B, and 10, the open arrow indicates the rotation direction in the outer peripheral portion of the bonded wafer 11, and for the sake of explanation, the bottom surface 13d1 of the first step portion 13d is illustrated.

When edge trimming is to be applied to the bonded wafer 11 by the second cutting blade 24, the lower end 24a of the second cutting blade 24 does not necessarily maintain a certain depth at all times and moves up and down within a certain range along the Z-axis direction from the set depth position (for example, a range of ±0.5 μm).

Hence, when the thickness of the joining layer 17 is 1.0 μm and, as illustrated in FIG. 9A, a set depth position 24a₁ is within the joining layer 17 and is higher than the depth position 17b that represents half the thickness of the joining layer 17 (that is, a position close to the first wafer 13), with the bottom surface 13d1 of the first step portion 13d being used as the reference, an uncut region of the first wafer 13 is generated.

FIG. 9A is a schematic view illustrating a first comparative example in which the second cutting step S40 is performed by down-cutting. In FIG. 9A, a trajectory 24a₂ of the lower end 24a in the second cutting step S40 is indicated by a solid line, and the uncut region of the first wafer 13 is hatched.

In contrast, as illustrated in FIG. 9B, when the set depth position 24a₁ is within the joining layer 17 and is lower than the depth position 17b that represents half the thickness of the joining layer 17 (that is, a position closer to the second wafer 15), with the bottom surface 13d₁ of the first step portion 13d being used as a reference, a region where the second wafer 15 is exposed by the joining layer 17 being removed is generated.

FIG. 9B is a schematic view illustrating a second comparative example in which the second cutting step S40 is performed by down-cutting. Note that, in FIG. 9B, the trajectory 24a₂ of the lower end 24a in the second cutting step S40 is indicated by a solid line, and the region where the second wafer 15 is exposed is hatched.

In contrast, FIG. 10 is a schematic view illustrating the manner of performing the second cutting step S40 by up-cutting, as in the present embodiment. As described above, up-cutting causes high cutting load on the second cutting blade, compared to down-cutting.

Hence, when the set depth position 24a1 is within the thickness range of the joining layer 17 and the lower end 24a of the second cutting blade 24 has reached the joining layer 17 in the actual cutting processing, the actually cut depth would be within a range of approximately 35% along the Z-axis direction from the set depth position 24a1, for example.

At this time, the joining layer 17 that has a thickness of 1.0 μm is apparently equivalent to having a thickness of 2.9 μm (=1 μm/0.35). Accordingly, when the set depth position 24a₁ is set to the depth position 17b that represents half the thickness of the joining layer 17, even when the set depth position 24a₁ is deviated upward or downward by 0.5 μm from the depth position 17b, the lower end 24a of the second cutting blade 24 would fall within the thickness range of the joining layer 17.

Note that, even when the depth position 24a₁ is to be set to a position where the second wafer 15 is present and which is near the face side 15a in the Z-axis direction, adopting up-cutting in the second cutting step S40 makes it possible to completely remove the first wafer 13 and to expose the joining layer 17 in the circumferential direction of the bonded wafer 11, without cutting the second wafer 15, owing to the relatively high cutting load.

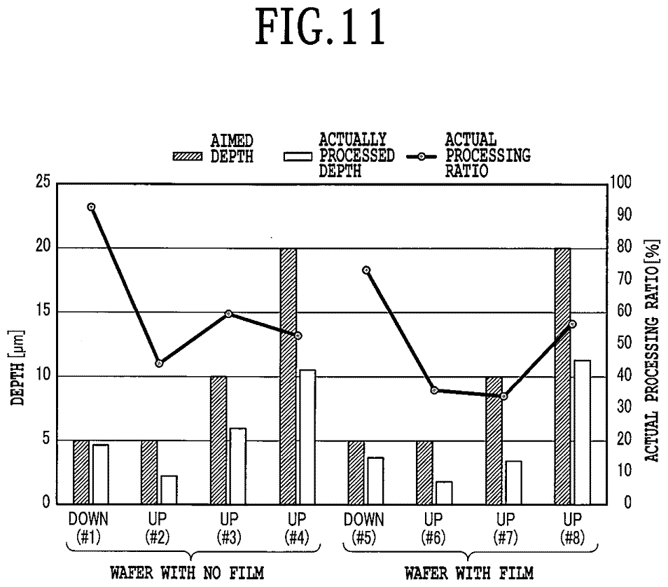

Next, with reference to FIG. 11, a result of experiment related to the difference between down-cutting and up-cutting is explained. FIG. 11 is a view indicating the result of experiment of confirming the difference between down-cutting and up-cutting. #1 through #4 in FIG. 11 indicate the result of experiment in which the abovementioned second cutting blade 24 is caused to cut into a silicon single crystalline substrate that has no silicon oxide film corresponding to the joining layer 17 (that is, a wafer with no film).

#5 through #7 in FIG. 11 indicate the result of experiment in which the second cutting blade 24 is caused to cut into only the silicon oxide film in the silicon single crystalline substrate which has, on one surface, a silicon oxide film corresponding to the joining layer 17 (that is, a wafer with a film) (that is, the silicon oxide film is cut in a state in which the lower end 24a of the second cutting blade 24 is positioned inside the silicon oxide film). #8 in FIG. 11 indicates the result of experiment in which the second cutting blade 24 is caused to further cut into the silicon single crystalline substrate beyond the silicon oxide film, in the wafer with a film.

The bar graph with a diagonal line represents an aimed depth [μm] (that is, the set depth position 24a₁), while an open bar graph represents an actually processed depth [μm] (that is, a depth actually cut when the depth position 24a₁ is set). DOWN indicates the down-cutting described above, while UP indicates the up-cutting described above.

Note that the actually processed depth is an average value of the depth at eight points separated at substantially equal intervals in the circumferential direction of the wafer with no film and the wafer with a film. Moreover, the actual processing ratio (%) is calculated by {(actually processed depth/aimed depth)×100}.

In the wafer with no film, the actual processing ratio in #1 was approximately 93%. In contrast, the actual processing ratio in #2 was approximately 44%, the actual processing ratio in #3 was approximately 60%, and the actual processing ratio in #4 was approximately 53%. As obvious from #2, #3, and #4, in up-cutting, the cutting load on the cutting blade is high, and cutting cannot be performed to reach a position of the aimed depth.

Meanwhile, in the wafer with a film, the actual processing ratio in #5 was approximately 73%. In contrast, the actual processing ratio in #6 was approximately 36%, the actual processing ratio in #7 was approximately 348, and the actual processing ratio in #8 was approximately 568. As obvious from a comparison between #5, #6, and #7, when the silicon oxide film is cut by up-cutting, the cutting load on the cutting blade remarkably increased. In the embodiment described above, actively utilizing the difficulty in cutting the silicon oxide film by up-cutting makes it possible to leave the joining layer 17 but completely remove the first wafer 13 over the entire circumferential direction of the bonded wafer 11.

Other structures, methods, and the like according to the present embodiment can be implemented with appropriate modifications within a range not departing from the scope of object of the present invention. For example, a dicing saw that has one spindle (that is, the first spindle 10 and the second spindle 20 are the same) may be used. In this case, in the first cutting step S20 and the second cutting step S40, the same cutting blade is used as the first cutting blade 14 and the second cutting blade 24 by being mounted on the one spindle described above.

Consistently using a coarse cutting blade corresponding to the first cutting blade 14 makes it possible to relatively efficiently advance the processing work in the first cutting step S20, while consistently using a finish cutting blade corresponding to the second cutting blade 24 makes it possible to maintain the processing quality in the second cutting step S40 at a relatively high level.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A bonded wafer processing method for a bonded wafer in which a first wafer and a second wafer are bonded with a joining layer sandwiched therebetween, the method comprising:
holding, on a holding table rotatable about a predetermined rotational shaft, the bonded wafer such that the first wafer is exposed;
after the holding the bonded wafer, forming, in an outer peripheral portion of the first wafer, a first step portion having a depth that does not reach the second wafer and by which the first wafer remains, by rotating the holding table about the rotational shaft in a state in which a first cutting blade mounted to a distal end portion of a first spindle is caused to cut into the outer peripheral portion of the first wafer while being rotated about the first spindle; and
after the forming the first step portion, removing the outer peripheral portion of the first wafer by rotating the holding table about the rotational shaft in a state in which a second cutting blade mounted to a distal end portion of a second spindle is rotated about the second spindle while a lower end of the second cutting blade is positioned to a position that is closer to the second wafer than to a bottom surface of the first step portion in a thickness direction of the bonded wafer and at which the joining layer is present, wherein,
in the removing the outer peripheral portion of the first wafer, the second cutting blade and the holding table are rotated such that a direction of a velocity vector of the lower end of the second cutting blade becomes opposite a direction of a velocity vector of the bonded wafer at a position corresponding to the lower end.

2. The bonded wafer processing method according to claim 1, further comprising:
after the forming the first step portion but before the removing the outer peripheral portion of the bonded wafer, measuring a remaining thickness of the first wafer that remains between the bottom surface of the first step portion and the second wafer, wherein,
in the removing the outer peripheral portion of the first wafer, a position of the lower end of the second cutting blade is set according to the remaining thickness.

3. The bonded wafer processing method according to claim 2, wherein, in the measuring the remaining thickness of the first wafer, the remaining thickness of the first step portion is measured with use of a non-contact thickness gage that is capable of measuring a thickness without coming into contact with the bonded wafer.
